(19) United States
(12) Patent Application Publication
(10) Pub. No.: US 2004/0219796 A1
(43) Pub. Date: Nov. 4, 2004

(54) Plasma etching process

(76) Inventor: Chih-Ning Wu, Hsinchu (TW)

Correspondence Address: J.C. Patents, Inc., Suite 250, 4 Venture, Irvine, CA, 92618, US

(21) Appl. No.: 10/428,507

(22) Filed: May 1, 2003

(51) Int. Cl. H01L 21/302; H01L 21/461

(52) U.S. Cl. 438/709

(57) ABSTRACT

A plasma etching process is described. A substrate having a low-k material layer and a metal hard mask layer sequentially formed thereon is provided, wherein the metal hard mask layer exposes a portion of the low-k material layer. The low-k material layer is then etched with plasma of a gas mixture of helium (He) and at least one fluorinated hydrocarbon by using the metal hard mask layer as a mask.

### BACKGROUND OF THE INVENTION

1. Field of the Invention

The present invention relates to a semiconductor process. More particularly, the present invention relates to a plasma etching process free of organo-metallic polymer contamination.

2. Description of the Related Art

In advanced semiconductor processes like 90 nm CMOS processes, 193 nm photoresist materials are required for forming small patterns. In the meantime, low-resistance metal materials like copper and low-k dielectric materials are usually adopted in multi-level interconnect structures for reducing RC delay effect. As a low-k material layer is to be patterned using a 193 nm photoresist material, a metal hard mask layer is required since the dry-etching resistance of a 193 nm photoresist material is low.

In the prior art, a low-k material layer is dry-etched with plasma generated from a gas mixture of Ar/CF₄/C₄F₈/N₂, Ar/CF₄/C₄F₈/O₂ or Ar/N₂/C₄F₈. A metal hard mask layer is more resistant to the plasma than a conventional SiN hard mask layer in such an etching process, however, organo-metallic polymer is easily formed contaminating the substrate because of back-sputtering and bombardment effects on the metal hard mask layer caused by Ar ions. For example, in an etching process for forming dual damascene openings, organo-metallic polymer is easily deposited on sidewalls of via holes and trenches. The organo-metallic polymer is difficult to remove, and will alter the resistance of via plugs and conductive lines that are formed later.

### SUMMARY OF THE INVENTION

In view of the forgoing, this invention provides a plasma etching process that is free of organo-metallic polymer contamination as a metal layer is also exposed in the plasma.

This invention also provides a plasma etching process utilizing a metal hard mask layer, which is free of organo-metallic polymer contamination.

This invention further provides a dual damascene process that is based on the plasma etching process of this invention.

In the plasma etching process of this invention, a gas mixture of helium (He) and at least one fluorinated hydrocarbon is used to generate plasma for etching a low-k material, while a metal layer is also exposed in the plasma.

In the plasma etching process utilizing a metal hard mask layer of this invention, a substrate having a low-k material layer and a metal hard mask layer sequentially formed thereon is provided, wherein the metal hard mask layer exposes a portion of the low-k material layer. The low-k material layer is then etched with plasma of a gas mixture of helium (He) and at least one fluorinated hydrocarbon by using the metal hard mask layer as a mask. The etching step may define a via hole, a trench, or a dual damascene opening in the low-k material layer.

The dual damascene process of this invention is described as follows. A substrate having a stack of a low-k material layer and a metal hard mask layer thereon is provided, wherein the low-k material layer has a hollow of via-hole pattern therein, and the metal hard mask layer is defined with a trench pattern over the hollow. The low-k material layer is then etched with plasma of a gas mixture of helium (He) and at least one fluorinated hydrocarbon to form a trench in the low-k material layer with the metal hard mask layer as a mask, and to deepen the hollow to complete a via hole in the low-k material layer.

In this invention, the bombardment and back sputtering effects on the metal (hard mask) layer is significantly reduced since helium ions are much lighter than argon ions, and formation of organo-metallic polymer therefore can be prevented. Therefore, by utilizing the dual damascene process based on the plasma etching process of this invention, organo-metallic polymer is not deposited on sidewalls of via holes and trenches, and the resistance of via plugs and conductive lines will not shift.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1-6 illustrate a dual damascene process according to a preferred embodiment of this invention in a cross-sectional view, the dual damascene process being based on the plasma etching process of this invention.

### DESCRIPTION OF THE PREFERRED EMBODIMENTS

The present invention will be further explained with a dual damascene process as a preferred embodiment. However, the present invention is not restricted to use in dual damascene processes, and can be used in any case where a low-k material is etched with a metal layer being exposed in the etching plasma simultaneously.

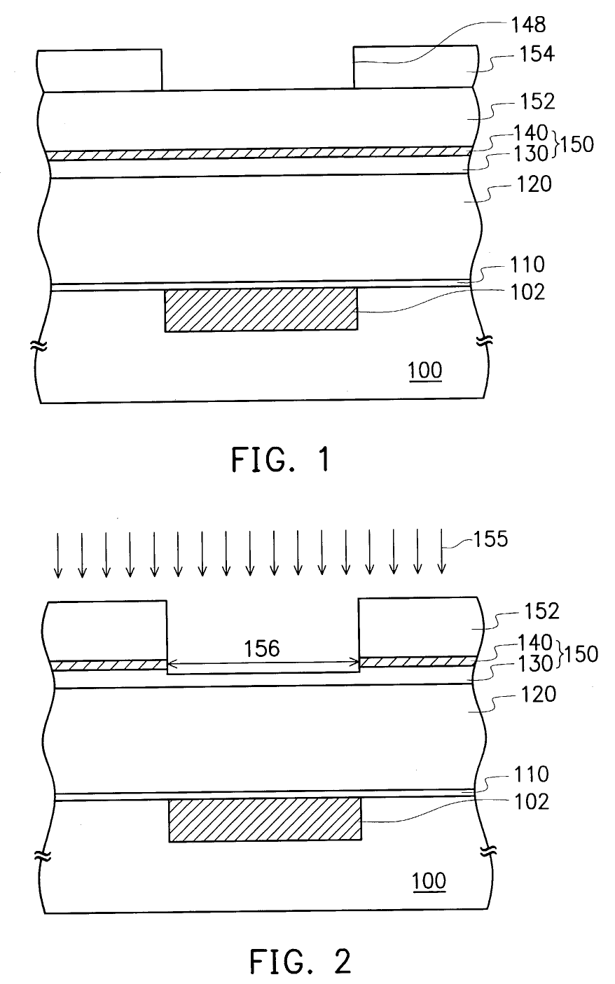

FIGS. 1-6 illustrate a dual damascene process according to a preferred embodiment of this invention in a cross-sectional view. The dual damascene process is based on the plasma etching process of this invention, and may be a 90 nm semiconductor process.

Referring to FIG. 1, a substrate 100 is provided with a conductive layer 102 to be connected formed therein, wherein the conductive layer 102 may comprise a low-resistance metallic material like copper. A protective layer 110, such as a SiN layer, is formed on the substrate 100 covering the conductive layer 102. A low-k material layer 120 is formed on the protective layer 110, comprising a material such as porous silicon oxide, hydrogen silsesquioxane (HSQ), methyl silsesquioxane (MSQ) or fluorinated glass (FSG). A non-metal hard mask layer 130 and a metal hard mask layer 140, which two constitute a hard mask layer 150 together, are sequentially formed on the low-k material layer 120. The non-metal hard mask layer 130 may comprise SiC, and the metal hard mask layer 140 comprises TiN or TaN, for example. Thereafter, a bottom anti-reflection coating (BARC) 152 and a photoresist layer 154 having a trench pattern 148 of a dual damascene structure are sequentially formed on the metal hard mask layer 140, wherein the photoresist layer 154 may comprise a 193 nm photoresist material.

Referring to FIGS. 1-2, anisotropic etching 155 is performed with the photoresist layer 154 (FIG. 1) as a mask to etch away the exposed BARC 152 and then transfer the trench pattern 148 to the hard mask layer 150, while the trench pattern on the hard mask layer 150 is labeled with “156”. It is noted that the photoresist layer 154 has been completely etched away, and the underlying BARC 152 is exposed serving as a new etching mask in FIG. 2.

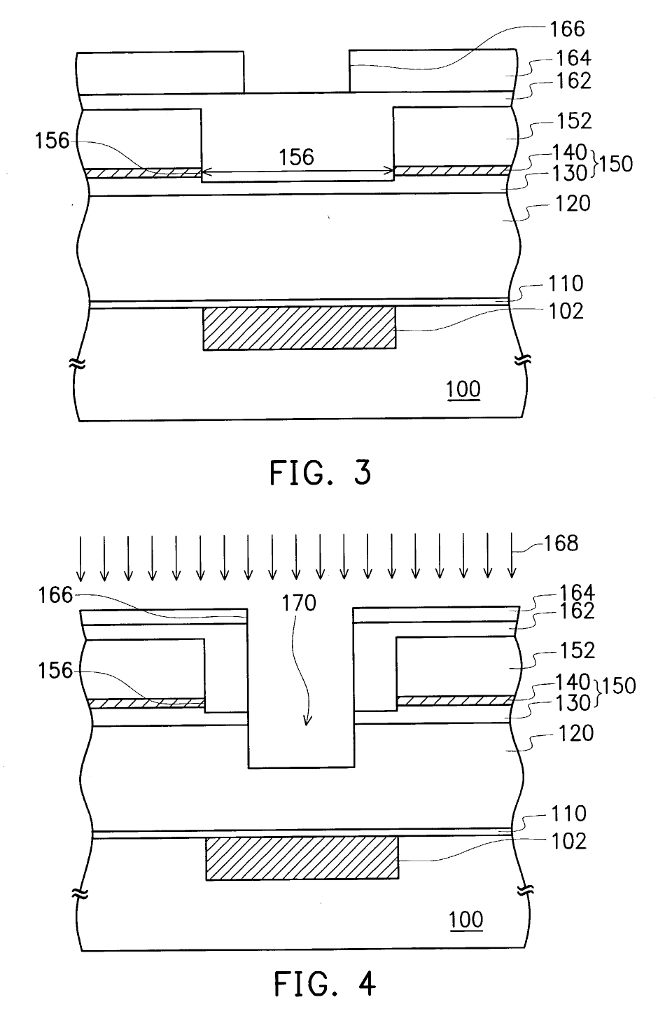

Referring to FIG. 3, a new BARC 162 and a photoresist layer 164 having a via-hole pattern 166 of the dual damascene structure are sequentially formed on the substrate 100, wherein the via-hole pattern 166 is located over the trench pattern 156 in the hard mask layer 150.

Referring to FIGS. 3-4, anisotropic etching 168 is performed with the photoresist layer 164 as a mask to sequentially etch away the BARC 162 and the non-metal hard mask layer 130 exposed in the via-hole pattern 166, and then partially etch the exposed low-k material layer 120 to form a hollow 170 of via-hole pattern in the low-k material layer 120.

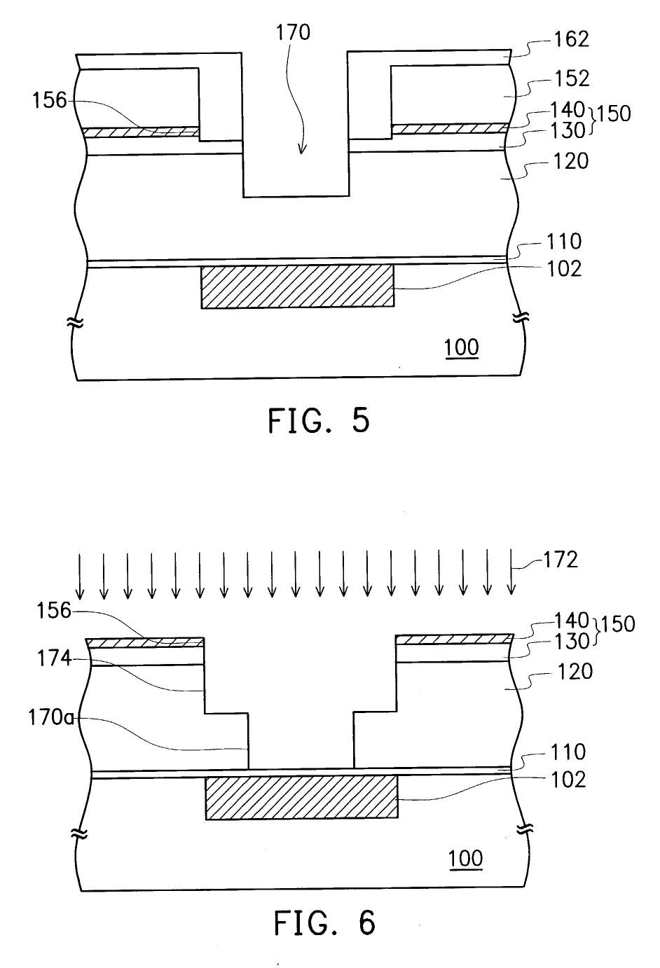

Referring to FIG. 5, a photoresist stripping process is performed to completely remove the remaining photoresist layer 164. The photoresist stripping process utilizes, for example, an alkaline stripping solution such as 3% NaOH solution.

Referring to FIG. 6, anisotropic etching 172 is performed with plasma of a gas mixture of He and at least one fluorinated hydrocarbon like CF₄, and the gas mixture may further include another fluorinated hydrocarbon, such as C₄F₈ or C₄F₆, for better control of the etching process. As He/CF₄/C₄F₈ are used as etching gases, it is preferable that He is introduced with a flow rate of 75-500 sccm, CF₄ with a flow rate of 18-30 sccm, and C₄F₈ with a flow rate of 3-8 sccm. After the bottom anti-reflection coatings 162 and 152 (FIG. 5) are etched away, the metal hard mask layer 140 serves as a new etching mask. The low-k material layer 120 under the trench pattern 156 but not under the hollow 170 is etched with the metal hard mask layer 140 as a mask after the exposed non-metal hard mask layer 130 is removed, whereby a trench 174 is formed in the low-k material layer 120. Meanwhile, the depth of the hollow 170 of via-hole pattern is continuously increased because of the etching effect, so that a via hole 170a is completed in the low-k material layer 120 finally.

The subsequent processes for completing a dual damascene structure include removing the exposed protective layer 110, removing the metal hard mask layer 140 and filling a metallic material into the via hole 170a and the trench 174 to form a via plug and a trench, etc. The descriptions of these processes are omitted here since they are well known in the art.

In this invention, the bombardment and back sputtering effects on the metal (hard mask) layer is significantly reduced since helium ions are much lighter than argon ions, and formation of organo-metallic polymer therefore can be prevented. Therefore, by utilizing the dual damascene process based on the plasma etching process of this invention, organo-metallic polymer is not deposited on sidewalls of via holes and trenches, and the resistance of via plugs and conductive lines will not shift.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

What is claimed is:

1. A plasma etching process, comprising:
providing a substrate having a metal layer and a low-k material thereon; and
etching the low-k material with a plasma of a gas mixture of helium (He) and at least one fluorinated hydrocarbon, while the metal layer is also exposed in the plasma.

2. The plasma etching process of claim 1, wherein the fluorinated hydrocarbon comprises CF₄.

3. The plasma etching process of claim 2, wherein the gas mixture further comprises another fluorinated hydrocarbon, being C₄F₈ or C₄F₆.

4. The plasma etching process of claim 1, wherein the low-k material is selected from a group consisting essentially of porous silicon oxide, hydrogen silsesquioxane (HSQ), methyl silsesquioxane (MSQ) and fluorinated glass (FSG).

5. A plasma etching process, comprising:
providing a substrate having a low-k material layer and a metal hard mask layer sequentially formed thereon, the metal hard mask layer exposing a portion of the low-k material layer; and
etching the low-k material layer with a plasma of a gas mixture of helium (He) and at least one fluorinated hydrocarbon by using the metal hard mask layer as a mask.

6. The plasma etching process of claim 5, wherein the fluorinated hydrocarbon comprises CF₄.

7. The plasma etching process of claim 6, wherein the gas mixture further comprises another fluorinated hydrocarbon, being C₄F₈ or C₄F₆.

8. The plasma etching process of claim 7, wherein He is introduced with a flow rate of 75-500 sccm, CF₄ with a flow rate of 18-30 sccm, and C₄F₈ with a flow rate of 3-8 sccm.

9. The plasma etching process of claim 5, wherein the low-k material layer comprises a material selected from a group consisting essentially of porous silicon oxide, hydrogen silsesquioxane (HSQ), methyl silsesquioxane (MSQ) and fluorinated glass (FSG).

10. The plasma etching process of claim 5, wherein the metal hard mask layer comprises TiN or TaN.

11. The plasma etching process of claim 5, wherein etching the low-k material layer defines a via hole, a trench, or a dual damascene opening in the low-k material layer.

12. A dual damascene process, comprising:
providing a substrate having a stack of a low-k material layer and a metal hard mask layer thereon, wherein the low-k material layer has a hollow of via-hole pattern therein, and the metal hard mask layer is defined with a trench pattern over the hollow; and
etching the low-k material layer with a plasma of a gas mixture of helium (He) and at least one fluorinated hydrocarbon to form a trench in the low-k material layer by using the metal hard mask layer as a mask, and to deepen the hollow to complete a via hole in the low-k material layer.

13. The dual damascene process of claim 12, wherein the fluorinated hydrocarbon comprises CF₄.

14. The dual damascene process of claim 13, wherein the gas mixture further comprises another fluorinated hydrocarbon, being C₄F₈ or C₄F₆.

15. The dual damascene process of claim 14, wherein He is introduced with a flow rate of 75-500 sccm, CF₄ with a flow rate of 18-30 sccm, and C₄F₈ with a flow rate of 3-8 sccm.

16. The dual damascene process of claim 12, wherein the low-k material layer comprises a material selected from a group consisting essentially of porous silicon oxide, hydrogen silsesquioxane (HSQ), methyl silsesquioxane (MSQ) and fluorinated glass (FSG).

17. The dual damascene process of claim 12, wherein the metal hard mask layer comprises TiN or TaN.

18. The dual damascene process of claim 12, wherein providing the substrate having a stack of the low-k material layer and the metal hard mask layer thereon comprises:
sequentially forming a blanket low-k material layer and a blanket metal layer on a substrate;
defining the trench pattern in the blanket metal layer; and
forming the hollow of via-hole pattern in the blanket low-k material layer under the trench pattern.

19. The dual damascene process of claim 18, wherein defining the trench pattern in the blanket metal layer comprises:
forming a bottom anti-reflection coating (BARC) on the blanket metal layer;
forming a photoresist layer having the trench pattern on the bottom anti-reflection coating; and
using the photoresist layer as a mask to etch away the exposed bottom anti-reflection coating and then transfer the trench pattern to the blanket metal layer.

20. The dual damascene process of claim 18, wherein forming the hollow of via-hole pattern in the blanket low-k material layer under the trench pattern comprises:
forming a bottom anti-reflection coating (BARC) on the substrate;
forming a photoresist layer having the via-hole pattern on the bottom anti-reflection coating; and
using the photoresist layer as a mask to etch away the exposed bottom anti-reflection coating and then partially etch the exposed low-k material layer to form the hollow.

21. The dual damascene process of claim 12, wherein the stack further comprises a non-metal hard mask layer directly under the metal hard mask layer.

22. The dual damascene process of claim 21, wherein the non-metal hard mask layer comprises silicon carbide (SiC).
